(19) United States
(12) Patent Application Publication
(10) Pub. No.: US 2011/0315976 A1
(43) Pub. Date: Dec. 29, 2011

(54) COMPOUNDS USABLE AS MATERIALS FOR A HOLE INJECTION LAYER OR HOLE TRANSPORT LAYER, AND ORGANIC LIGHT-EMITTING DIODE USING SAME

(76) Inventors: Kwang Suck Suh, Seongnam-si (KR); Jong Eun Kim, Seoul (KR); Tae Young Kim, Seoul (KR); Tae Hee Lee, Gyeonggi-do (KR); Min Won Suh, Gyeonggi-do (KR)

(21) Appl. No.: 13/255,456

(22) PCT Filed: Mar. 11, 2010
(86) PCT No.: PCT/KR2010/001538

§ 371 Date: Sep. 8, 2011

(30) Foreign Application Priority Data
Mar. 11, 2009 (KR) 10-2009-0020863

(51) Int. Cl. H01L 51/54; H01B 1/12; C08G 73/06; C08G 75/06

(52) U.S. Cl. 257/40; 528/380; 252/500; 257/E51.024

(57) ABSTRACT

The present invention relates to a compound which can be used as a material for a hole injection layer or a hole transporting layer of organic light emitting diodes (OLEDs) or electroluminescent elements. The compound is synthesized into a conductive polymer using liquid polymer ions, and this conductive polymer can be used as a material for a hole injection layer or a hole transporting layer of an organic light emitting diode. The compound is advantageous in that a hole injection layer formed using the compound has more excellent performance and can be maintained over a longer lifespan than a hole injection layer formed using conventional compounds.

### TECHNICAL FIELD

The present invention relates to a compound which can be used as a material for a hole injection layer or a hole transporting layer in connection with organic light emitting diodes (OLEDs) or electroluminescent elements. The compound is synthesized into a conductive polymer using a polymer-ionic liquid, and this conductive polymer can be used as a material for a hole injection layer or a hole transporting layer of an organic light emitting diode. The hole injection layer formed using the compound has more excellent performance and can be maintained over a longer lifespan than a hole injection layer formed using conventional compounds.

### BACKGROUND ART

Advances have been made in liquid crystal displays (LCDs) since cathode ray tubes (CRTs), which are imaging apparatuses using electron guns, were replaced by liquid crystal displays (LCDs) which use liquid crystal orientation. These crystal displays (LCDs) are made using technologies for transmitting light using liquid crystal orientation attributable to the application of a voltage, and these technologies are generally used to make most imaging apparatuses.

However, in order to use liquid crystal orientation, it is required that a voltage be applied to form an electric field, and that various apparatuses, such as an apparatus for transmitting light to both sides of a glass plate filled with liquid crystals, an apparatus for generating light and the like, are provided because afterimages remain when liquid crystals do not become oriented instantaneously or because image signals must penetrate liquid crystals. For example, images can be seen only when light guide plates for guiding light, diffusion films for uniformly diffusing light, prism films for transmitting light in all directions, and polarizing films for polarizing light are present, the films of which respectively face each other. Therefore, there are some problems of it being difficult to decrease the thickness of a display panel to a predetermined thickness or less and of light loss from a light source to user's eyes being excessive.

An organic light emitting diode (OLED), which is a display device which can overcome the above problems, is formed by laminating several material layers to a thickness of several tens of nanometers. In this case, when a voltage is applied to the organic light emitting diode, light is emitted from the material layers of the organic light emitting diode, and thus an additional light source is not required, so that the organic light emitting diode is advantageous in that several functional films used in an imaging apparatus using liquid crystal orientation technologies need not be used.

FIG. 1 shows a structure of an organic light emitting diode. The organic light emitting diode includes: a transparent electrode layer which is made of indium tin oxide (ITO) doped with indium (In) and to which a voltage is applied; a hole injection layer formed on the transparent electrode layer to a thickness of several tens of nanometers; a hole transporting layer made of N,N′-diphenyl-N,N′-bis(1-naphthyl)-(1,1′-biphenyl)-4,4′-diamine (NPB) or the like and formed on the hole injection layer; a luminescent layer made of aluminum tris(8-hydroxyquinoline) (Alq₃) or the like and formed on the hole transporting layer; an electron injection layer made of LiF or the like and formed on the luminescent layer; and a metal electrode layer made of aluminum (Al) or the like and formed on the electron injection layer, a voltage being applied to the metal electrode layer. Here, when a positive voltage is applied to the transparent electrode layer and a negative voltage is applied to the metal electrode layer, light of a predetermined wavelength range is generated from the luminescent layer, and this light is sent to the outside through the transparent electrode layer. Therefore, the organic light emitting diode, like an LCD, does not need an additional light source, and, also, does not need an intermediate film for transferring the light.

However, although research and development into imaging apparatuses using organic light emitting diodes has been ongoing continuously, it is not yet easy to use the organic light emitting diodes to manufacture imaging apparatuses. The reason for this is that the organic light emitting diodes have a short lifespan. Early on, it was reported that the efficiency of organic light emitting diodes was improved by forming a thin film on an indium tin oxide (ITO) layer using poly(3,4-ethylenedioxythiophene:polystyrenesulfonate (hereinafter, referred to as “PEDOT:PSS”, manufactured by H. C. Starck Corp. as the grade name “AI4083”), which is a conductive polymer, as a material for a hole injection layer. However, it was impossible to remarkably improve the lifespan of organic light emitting diodes using the PEDOT:PSS. That is, when this PEDOT:PSS was used as a material for a hole injection layer, it was known that the lifespan of organic light emitting diodes was shortened with the passage of time when this PEDOT:PSS was applied to the ITO layer as a transparent electrode layer and then used because indium was extracted from the ITO layer due to the high acidity of the PEDOT:PSS.

In order to overcome such a problem, currently, a technology for forming a hole injection layer using copper phthalocyanine (CuPc), which is a low molecular weight material, by deposition is being used. In this technology, the lifespan of organic light emitting diodes becomes longer compared to when the PEDOT:PSS is used because indium is not extracted from a transparent electrode layer. However, this technology is known as one wherein it is difficult to realize large-sized imaging apparatuses although it is possible to realize small-sized imaging apparatuses because a hole injection layer is formed by deposition.

Therefore, it is required to develop new materials which can be used as a material for a hole injection layer or a hole transporting layer, which can be used to realize large-area displays, and which can increase the lifespan of organic light emitting diodes compared to when the PEDOT:PSS is used.

### DISCLOSURE

### Technical Problem

Accordingly, the present invention has been made keeping in mind the above problems occurring in the prior art, and an object of the present invention is to provide a new compound which can be used as an organic material for a hole injection layer or a hole transporting layer and which can improve the lifespan of organic light emitting diodes.

Another object of the present invention is to provide a new organic light emitting diode using the compound.

Objects to be accomplished by the present invention are not limited to the above-mentioned objects, and other objects can be clearly understood by those skilled in the art by the following descriptions.

### Technical Solution

In order to accomplish the above objects, the present invention provides a compound represented by Formula 1 below, which can be neutralized by dispersing it in an organic solvent to solve the problem of high acidity and water dispersibility of conventional polystyrenesulfonate:

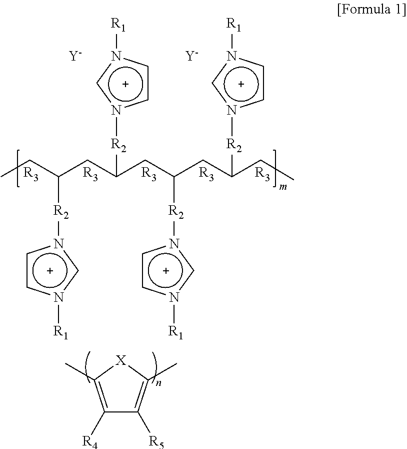

wherein R₁ and R₃ are equal to or different from each other, are each independently selected from hydrogen and a hydrocarbon group of 1 to 12 carbon atoms, and selectively include one or more hetero atoms; R₂ is a hydrocarbon group of 0 to 16 carbon atoms, and selectively includes one or more hetero atoms; Y⁻ represents an anion of an imidazolium-based polymer-ionic liquid; R₄ and R₅ are each independently selected from hydrogen, halogen and a hydrocarbon group of 1 to 15 carbon atoms, and selectively include one or more hetero atoms, or R₄ and R₅ are each independently selected from alkylene, alkenylene, alkenyloxy, alkenyldioxy, alkynyloxy and alkynyldioxy, which constitute a cycloaromatic or cycloaliphatic compound of 3 to 8 atoms, and selectively include one or more hetero atoms; and X represents any one selected from among NH, NR, S, O, Se, and Te.

The compound represented by Formula 1 above can be used as a material for a hole injection layer or a hole transporting layer of organic light emitting diodes and the like.

### Advantageous Effects

The compound of the present invention is advantageous in that it has very low acidity because a conductive polymer is dispersed in an organic solvent using an imidazolium-based polymer-ionic liquid.

A conventional conductive polymer is problematic because, when it is used as a material for a hole injection layer of an organic light emitting diode, the lifespan of the organic light emitting diode is rapidly shortened because it has very high acidity, but the compound of the present invention is advantageous in that, when it is used as a material for a hole injection layer of an organic light emitting diode, the lifespan of the organic light emitting diode can be remarkably increased.

The compound of the present invention is advantageous because, when it is used as a material for a hole injection layer, it can be easily formed into a large-area hole injection layer using ink-jet printing or spin coating.

### BRIEF DESCRIPTION OF DRAWING

The above and other objects, features and advantages of the present invention will be more clearly understood from the following detailed description taken in conjunction with the accompanying drawing, in which:

FIG. 1 is a sectional view showing a structure of an organic light emitting diode prepared using a compound of the present invention.

### BEST MODE

Hereinafter, a method of preparing a compound (represented by Formula 1 above) according to the present invention will be described.

First, a conductive polymer is synthesized by mixing monomers and an oxidant with an imidazolium-based polymer-ionic liquid which is soluble in an organic solvent. The synthesized conductive polymer is washed with water or an aqueous solvent and then dried to obtain a particulate conductive polymer or is washed with an organic solvent to obtain a conductive polymer solution in which conductive polymer particles are dispersed in the organic solvent.

In the present invention, as represented by Formula 2 below, the imidazolium-based polymer-ionic liquid is polymeric compound including an organic cation having an imidazolium group and an organic or inorganic anion.

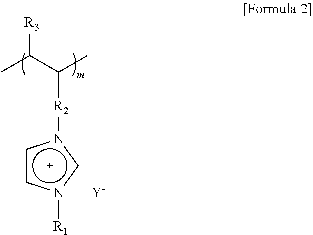

wherein R₁ and R₃ are equal to or different from each other, are each independently selected from hydrogen and a hydrocarbon group of 1 to 12 carbon atoms, and selectively include one or more hetero atoms; R₂ is a hydrocarbon group of 0 to 16 carbon atoms, and selectively includes one or more hetero atoms; and Y⁻ represents an anion of an imidazolium-based polymer-ionic liquid.

The imidazolium-based polymer-ionic liquid may have various physical and chemical characteristics depending on the combination of cations and anions. Preferably, it is advantageous to use an imidazolium-based polymer-ionic liquid which has high solubility in an organic solvent and which allows a conductive polymer to be stably dispersed in an organic solvent.

Examples of cationic components of the polymeric compound, represented by Formula 2, having an imidazolium group may include poly(1-vinyl-3-alkylimidazolium), poly(1-allyl-3-alkylimidazolium), poly(1-(meth)acryloyloxy-3-alkylimidazolium), and the like. Examples of the anion represented by Y⁻ of Formula 2 may include, but are not limited to, CH₃COO⁻, CF₃COO⁻, CH₃SO₃⁻, CF₃SO₃⁻, (CF₃SO₂)₂N⁻, (CF₃SO₂)₃C⁻, (CF₃CF₂SO₂)₂N⁻, C₄F₉SO₃⁻, C₃F₇COO⁻, and (CF₃SO₂) (CF₃CO)N⁻ in terms of solubility in an organic solvent.

As the imidazolium-based polymer-ionic liquid, a compound prepared by radical-polymerizing monomolecular compounds or a compound made of a polymer may be used.

In the present invention, the monomer for synthesizing a conductive polymer is represented by Formula 3 below:

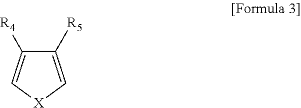

wherein R₄ and R₅ are each independently selected from hydrogen, halogen and a hydrocarbon group of 1 to 15 carbon atoms, and selectively includes one or more hetero atoms, or R₄ and R₅ are each independently selected from alkylene, alkenylene, alkenyloxy, alkenyldioxy, alkynyloxy and alkynyldioxy, which constitute a cycloaromatic or cycloaliphatic compound of 3 to 8 atoms, and selectively include one or more hetero atoms; and X represents any one selected from among NH, NR, S, O, Se, and Te.

The monomer represented by Formula 3 above is an organic substance including hetero atoms and having cyclic conjugate double bonds. These monomers are formed into a polymer by a polymerization reaction, and this polymer exhibits electroconductivity and allows holes to be easily injected.

The synthesis of the conductive polymer using the imidazolium-based polymer-ionic liquid may be conducted by the following two methods.

First, the imidazolium-based polymer-ionic liquid represented by Formula 2, the monomer represented by Formula 3, and an oxidant are dissolved in an organic solvent and then polymerized to obtain a conductive polymer solution in which a conductive polymer is dispersed in the organic solvent.

Second, a water-soluble imidazolium-based polymer-ionic liquid, the monomer represented by Formula 3, and an oxidant are mixed with each other in water and then polymerized to form an aqueous conductive polymer solution, and then anions included in the aqueous conductive polymer solution are substituted with Y⁻ (anions soluble in an organic solvent) to allow the conductive polymer to be dispersed in the organic solvent.

If any one of the above methods is used, a conductive polymer solution having high purity, uniform dispersibility in an organic solvent and low acidity can be obtained, as long as a suitable washing process is performed.

The oxidant used in the polymerization of the monomers is not particularly limited as long as it can induce a polymerization. Examples of the oxidant may include hydrogen peroxide, organic or inorganic peroxides, persulfates, peracids, peroxyacids, bromates, chlorates, perchlorates, and organic or inorganic salts of iron (III), chromium (IV), chromium (VI), manganese (VII), manganese (V), manganese (IV), vanadium (V), ruthenium (IV) and copper (II), and the like.

Since the conductive polymer synthesized as described above, that is, the compound of the present invention, is easily dispersed in an organic solvent, it can be used as a material for a hole injection layer or a hole transporting layer of an organic light emitting diode.

When the conductive polymer is used as a material for a hole injection layer or a hole transporting layer of an organic light emitting diode, the lifespan of the organic light emitting diode can be increased. It is preferred that the conductive polymer be dispersed in an organic solvent and then used. Examples of the organic solvent may include: alcohols such as methanol, ethanol, propanol, isopropanol, butanol, isobutanol and the like; ethers such as diethylether, dipropylether, dibutylether, butylethylether, tetrahydrofuran and the like; ether alcohols such as ethyleneglycol, propyleneglycol, ethyleneglycol monomethylether, ethyleneglycol monoethylether, ethyleneglycol monobutylether and the like; ketones such as acetone, methylethyl ketone, methylisobutyl ketone, cyclohexanone and the like; amides such as N-methyl-2-pyrrolidinone, 2-pyrrolidinone, N-methylformamide, N,N-dimethylformamide and the like; sulfoxides such as dimethyl sulfoxide, diethyl sulfoxide and the like; sulfones such as diethyl sulfone, tetramethylene sulfone and the like; nitriles such as acetonitrile, benzonitrile and the like; amines such as alkylamine, cyclic amine, aromatic amine and the like; esters such as methyl butylate, ethyl butylate, propyl propionate and the like; carboxylic esters such as ethyl acetate, butyl acetate and the like; aromatic hydrocarbons such as benzene, ethyl benzene, chlorobenzene, toluene, xylene and the like; aliphatic hydrocarbons such as hexane, heptane, cyclohexane and the like; halogenated hydrocarbons such as chloroform, tetrachloroethylene, carbon tetrachloride, dichloromethane, dichloroethane and the like; organic carbonates such as propylene carbonate, ethylene carbonate, dimethyl carbonate, dibutyl carbonate, ethylmethyl carbonates, dibutyl carbonate and the like; nitromethane; nitrobenzene; and mixtures thereof. Among them, particularly, an aprotic polar solvent, such as N-methyl-2-pyrrolidinone, acetonitrile, tetrahydrofuran, dimethylformamide, dimethyl sulfoxide or propylene carbonate, may be used as the organic solvent.

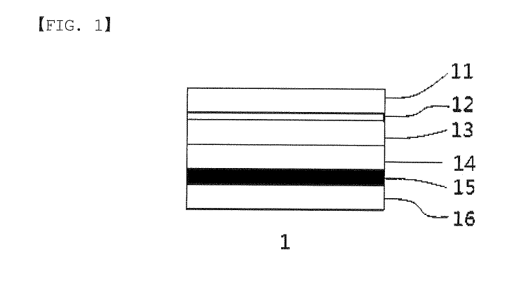

Hereinafter, an organic light emitting diode including a hole injection layer formed of a compound of the present invention, the compound being a conductive polymer which can be dispersed in an organic solvent, will be described with reference to FIG. 1. FIG. 1 shows an example of an organic light emitting diode including a hole injection layer formed using the compound of the present invention. It goes without saying that organic light emitting diodes having various structures can be manufactured by forming a hole injection layer using the compound of the present invention. As shown in FIG. 1, the organic light emitting diode of the present invention includes: an indium tin oxide (ITO) film 16 serving as a transparent cathode; a hole injection layer 15 formed on the indium tin oxide (ITO) film 16 and made of PEDOT which is a compound represented by Formula 1; a hole transporting layer 14 formed on the hole injection layer 15; a luminescent layer formed on the hole transporting layer 14; an electron injection layer 12 formed on the luminescent layer 13; and an anode 11 formed on the electron injection layer 12.

Hereinafter, a method of manufacturing an organic light emitting diode using a conductive polymer dispersed in an organic solvent according to the present invention will be described in detail.

First, a conductive polymer solution in which a conductive polymer is dispersed in an organic solvent is applied on the surface of an ITO film serving as a transparent electrode by a spin coating method to form a hole injection layer having a thickness of 5˜100 nm. Subsequently, as shown in FIG. 1, the above-mentioned layers are sequentially formed on the hole injection layer to manufacture an organic light emitting diode.

For example, the organic light emitting diode is manufactured by forming a hole transporting layer using N,N′-diphenyl-N,N′-bis(1-naphthyl)-(1,1′-biphenyl)-4,4′-diamine (NPB), forming a luminescent layer using aluminum tris(8-hydroxyquinoline) (Alq₃), forming a hole injection layer using LiQ and forming an anode using Al by vacuum deposition or sputtering.

The luminescent efficiency and lifespan of the organic light emitting diode was measured. As a result, it was found from the following Examples that the material used to form the hole injection layer according to the present invention was effective in increasing the lifespan of the organic light emitting diode.

Hereinafter, a method of manufacturing an organic light emitting diode by forming a hole injection layer using a conductive polymer dispersed in an organic solvent according to the present invention will be described in more detail with reference to the following Comparative Example 1 and Example 1. However, these Examples are set forth to illustrate the present invention, and the scope of the present invention is not limited thereto.

Further, in Comparative Example 1 and Example 1,3,4-ethylenedioxythiophene monomer was mainly used as the material for a hole injection layer. However, in the present invention, in addition to this monomer, monomers shown in Formula 3, such as pyrrole monomer, thiophene monomer and other conductive monomers, may be used.

### Comparative Example 1

In Comparative Example 1, an organic light emitting diode was manufactured using PEDOT:PSS (grade name: Clevios P AI4083, manufactured by H. C. Starck Corp. in Germany) which is commercially used as the material for a hole injection layer. In this case, the organic light emitting diode was configured such that it has a structure of ITO(150 nm)//AI4083(50 nm)//NPB(60 nm)//Alq(50 nm)//LiQ(1 nm)//Al(100 nm).

The characteristics of the organic light emitting diode of Comparative Example 1 are given in Table 1.

### Example 1

In Example 1, an organic light emitting diode was manufactured in the same manner as Comparative Example 1, except that a conductive polymer solution in which an imidazolium-based polymer-ionic liquid is dispersed in propylene carbonate as an organic solvent in an amount of 3 wt % was used as a material for the hole injection layer.

The conductive polymer solution used in Example 1 was prepared as follows. First, 1.5 g of poly(1-vinyl-3-ethylimidazolium bromide) having a weight average molecular weight of 170,000 g/mol and 1 g of 3,4-ethylenedioxythiophene as a monomer for synthesizing a conductive polymer were dissolved in 150 mL of water to form a mixed solution, and then ammonium peroxide as a polymerization initiator was added to the mixed solution drop by drop at a molar ratio of the ammonium peroxide to the monomer of 1.2, and simultaneously a polymerization reaction was conducted to obtain an aqueous conductive polymer. Subsequently, lithium bis(trifluoromethanesulfoneimide) as an alkali metal salt was added to the aqueous conductive polymer at a molar ratio of the lithium bis(trifluoromethanesulfoneimide) to poly(1-vinyl-2,3-ethylimidazolium)bromide of 1.2 to induce an anion exchange reaction. Subsequently, the precipitate obtained from the anion exchange reaction was washed, dried and then dispersed in propylene carbonate as an organic solvent in a solid content of 3% to prepare the conductive polymer solution.

The characteristics of the organic light emitting diode manufactured using the method of Example 1 are given in Table 1.

TABLE 1

| | Luminescent | | |
|---|---|---|---|
| | Efficiency | Lifespan test (at I = 48 mA/cm²) | |
| | (when 5 V | Initial | |
| | applied) | luminescent | Time reduced to |
| Class. | (cd/A) | efficiency (cd/m²) | 50% (hr) |
| Comp. Exp. 1 | 2.67 | 1050 | 22 |
| Exp. 1 | 2.89 | 1250 | 390 |

It can be seen from Table 1 that the luminescent efficiency (when 5V is applied) of the organic light emitting diode manufactured using the hole injecting material is equal to or more than that of the organic light emitting diode manufactured using a conventional hole injecting material, and that the lifespan of the organic light emitting diode manufactured using the hole injecting material is 10 times or more than that of the organic light emitting diode manufactured using a conventional hole injecting material.

### INDUSTRIAL APPLICABILITY

As described above, the compound of the present invention can be used in various fields, such as organic light emitting diodes, liquid crystal displays, etc.

1. A compound represented by Formula 1 below: 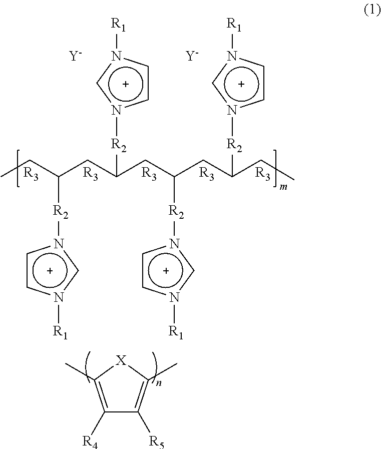
wherein R₁ and R₃ are equal to or different from each other, are each independently selected from hydrogen and a hydrocarbon group of 1 to 12 carbon atoms, and selectively include one or more hetero atoms; R₂ is a hydrocarbon group of 0 to 16 carbon atoms, and selectively includes one or more hetero atoms; Y⁻ represents an anion of an imidazolium-based polymer-ionic liquid; R₄ and R₅ are each independently selected from hydrogen, a halogen and a hydrocarbon group of 1 to 15 carbon atoms, and selectively include one or more hetero atoms, or R₄ and R₅ are each independently selected from alkylene, alkenylene, alkenyloxy, alkenyldioxy, alkynyloxy and alkynyldioxy, which constitute a cycloaromatic or cycloaliphatic compound of 3 to 8 atoms, and selectively include one or more hetero atoms; and X represents any one selected from among NH, NR, S, O, Se, and Te.

2. The compound according to claim 1, wherein the compound is prepared by mixing an imidazolium-based polymer-ionic liquid represented by Formula 2 below with a monomer represented by Formula 3 below to form a mixture and then polymerizing the mixture: 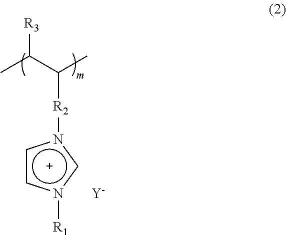
wherein R₁ and R₃ are equal to or different from each other, are each independently selected from hydrogen and a hydrocarbon group of 1 to 12 carbon atoms, and selectively include one or more hetero atoms; R₂ is a hydrocarbon group of 0 to 16 carbon atoms, and selectively includes one or more hetero atoms; and Y⁻ represents an anion of an imidazolium-based polymer-ionic liquid, and 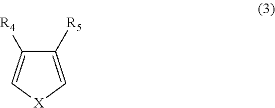
wherein R₄ and R₅ are each independently selected from hydrogen, a halogen and a hydrocarbon group of 1 to 15 carbon atoms, and selectively include one or more hetero atoms, or R₄ and R₅ are each independently selected from alkylene, alkenylene, alkenyloxy, alkenyldioxy, alkynyloxy and alkynyldioxy, which constitute a cycloaromatic or cycloaliphatic compound of 3 to 8 atoms, and selectively include one or more hetero atoms; and X represents any one selected from among NH, NR, S, O, Se, and Te.

3. The compound according to claim 2, wherein the imidazolium-based polymer-ionic liquid is a polymeric compound including an organic cation having an imidazolium group and an organic or inorganic anion.

4. The compound according to claim 2, wherein the monomer is an organic substance including hetero atoms and having cyclic conjugate double bonds; and the monomers are formed into a polymer by a polymerization reaction, and the polymer exhibits electroconductivity and allows holes to be easily injected.

5. The compound according to claim 4, wherein the monomer is any one selected from among a 3,4-ethylenedioxythiophene monomer, a pyrrole monomer, and a thiophene monomer.

6. The compound according to claims 2, wherein the cation of the imidazolium-based polymer-ionic liquid is selected from among poly(1-vinyl-3-alkylimidazolium), poly(1-allyl-3-alkylimidzolium), poly(1-(meth)acryloyloxy-3-alkylimidazolium), and the anion thereof is selected from among CH₃COO⁻, CF₃COO⁻, CH₃SO₃⁻, CF₃SO₃⁻, (CF₃SO₂)₂N⁻, (CF₃SO₂)₃C⁻, (CF₃CF₂SO₂)₂N⁻, C₄F₉SO₃⁻, C₃F₇COO⁻, and (CF₃SO₂) (CF₃CO)N⁻.

7. The compound according to claim 3, wherein the cation of the imidazolium-based polymer-ionic liquid is selected from among poly(1-vinyl-3-alkylimidazolium), poly(1-allyl-3-alkylimidzolium), poly(1-(meth)acryloyloxy-3-alkylimidazolium), and the anion thereof is selected from among CH₃COO⁻, CF₃COO⁻, CH₃SO₃⁻, CF₃SO₃⁻, (CF₃SO₂)₂N⁻, (CF₃SO₂)₃C⁻, (CF₃CF₂SO₂)₂N⁻, C₄F₉SO₃⁻, C₃F₇COO⁻, and (CF₃SO₂) (CF₃CO)N⁻.

8. The compound according to claim 1, wherein the compound is dispersed in an organic solvent.

9. The compound according to claim 8, wherein the organic solvent is an aprotic polar solvent.

10. A hole injecting material for an organic light emitting diode, the hole injecting material being prepared using the compound of claim 8.

11. An organic light emitting diode comprising a hole injection layer formed using the hole injection material of claim 10.

12. The organic light emitting diode according to claim 11, comprising:
a cathode;
the hole injection layer formed on the cathode using the hole injecting material;
a hole transporting layer formed on the hole injection layer;
a luminescent layer formed on the hole transporting layer;
an electron injection layer formed on the luminescent layer; and
an anode layer formed on the electron injection layer.

13. A method of preparing the compound of claim 1,
wherein the imidazolium-based polymer-ionic liquid represented by Formula 2, the monomer represented by Formula 3, and an oxidant are dissolved in an organic solvent and then polymerized to obtain a conductive polymer solution in which a conductive polymer is dispersed in the organic solvent, or
wherein a water-soluble imidazolium-based polymer-ionic liquid, the monomer represented by Formula 3, and an oxidant are mixed and then polymerized to form an aqueous conductive polymer solution, and then anions included in the aqueous conductive polymer solution are substituted with Y⁻ (anions soluble in an organic solvent) to allow the conductive polymer to be dispersed in the organic solvent.
wherein a water-soluble imidazolium-based polymer-ionic liquid, the monomer represented by Formula 3, and an oxidant are mixed and then polymerized to form an aqueous conductive polymer solution, and then anions included in the aqueous conductive polymer solution are substituted with YΔ (anions soluble in an organic solvent) to allow the conductive polymer to be dispersed in the organic solvent.

14. The compound according to claim 3, wherein the monomer is an organic substance including hetero atoms and having cyclic conjugate double bonds; and the monomers are formed into a polymer by a polymerization reaction, and the polymer exhibits electroconductivity and allows holes to be easily injected.

15. The compound according to claim 14, wherein the monomer is any one selected from among a 3,4-ethylenedioxythiophene monomer, a pyrrole monomer, and a thiophene monomer.

16. The compound according to claim 4, wherein the cation of the imidazolium-based polymer-ionic liquid is selected from among poly(1-vinyl-3-alkylimidazolium), poly(1-allyl-3-alkylimidzolium), poly(1-(meth)acryloyloxy-3-alkylimidazolium), and the anion thereof is selected from among CH₃COO⁻, CF₃COO⁻, CH₃SO₃⁻, CF₃SO₃⁻, (CF₃SO₂)₂N⁻, (CF₃SO2)₃C⁻, (CF₃CF₂SO₂)₂N⁻, C₄F₉SO₃⁻, C₃F₇COO⁻, and (CF₃SO₂) (CF₃CO)N⁻.

17. The compound according to claim 5, wherein the cation of the imidazolium-based polymer-ionic liquid is selected from among poly(1-vinyl-3-alkylimidazolium) , poly(1-allyl-3-alkylimidzolium), poly(1-(meth)acryloyloxy-3-alkylimidazolium), and the anion thereof is selected from among CH₃COO⁻, CF₃COO⁻, CH₃SO₃⁻, CF₃SO₃⁻, (CF₃SO₂)₂N⁻, (CF₃SO₂)₃C⁻, (CF₃CF₂SO₂)₂N⁻, C₄F₉SO₃⁻, C₃F₇COO⁻, and (CF₃SO₂) (CF₃CO) N⁻.

18. The compound according to claim 14, wherein the cation of the imidazolium-based polymer-ionic liquid is selected from among poly(1-vinyl-3-alkylimidazolium), poly(1-allyl-3-alkylimidzolium), poly(1-(meth)acryloyloxy-3-alkylimidazolium), and the anion thereof is selected from among CH₃COO⁻, CF₃COO⁻, CH₃SO₃⁻, CF₃SO₃⁻, (CF₃SO₂)₂N⁻, (CF₃SO₂)₃C⁻, (CF₃CF₂SO₂)₂N⁻, C₄F₉SO₃⁻, C₃F₇COO⁻, and (CF₃SO₂) (CF₃CO) N⁻.

19. The compound according to claim 15, wherein the cation of the imidazolium-based polymer-ionic liquid is selected from among poly(1-vinyl-3-alkylimidazolium), poly(1-allyl-3-alkylimidzolium), poly(1-(meth)acryloyloxy-3-alkylimidazolium), and the anion thereof is selected from among CH₃COO⁻, CF₃COO⁻, CH₃SO₃⁻, CF₃SO₃⁻, (CF₃SO₂)₂N⁻, (CF₃SO₂)₃C⁻, (CF₃CF₂SO₂)₂N⁻, C₄F₉SO₃⁻, C₃F₇COO⁻, and (CF₃SO₂) (CF₃CO) N⁻.
